(19) United States
(12) Patent Application Publication
(10) Pub. No.: US 2015/0034377 A1
(43) Pub. Date: Feb. 5, 2015

(54) GLASS CORE SUBSTRATE AND METHOD FOR MANUFACTURING THE SAME

(71) Applicant: SAMSUNG ELECTRO-MECHANICS CO., LTD., Suwon (KR)

(72) Inventor: Tae Hong MIN, Suwon (KR)

(73) Assignee: SAMSUNG ELECTRO-MECHANICS CO., LTD., Suwon (KR)

(21) Appl. No.: 14/444,126

(22) Filed: Jul. 28, 2014

(30) Foreign Application Priority Data
Jul. 31, 2013 (KR) 10-2013-0090969

(51) Int. Cl. H05K 3/00; H05K 3/46; H05K 1/03; H05K 1/02; C03C 23/00; H05K 1/11

(52) U.S. Cl. CPC H05K 3/00; C03C 23/0025; H05K 1/115; H05K 1/0306; H05K 1/0298; H05K 1/0271; H05K 3/0094; H05K 3/4685; H05K 3/4605; B32B 2307/206; B32B 2457/08; H05K 2201/09563; H05K 2201/09645
USPC 174/264; 156/253

(57) ABSTRACT

Disclosed herein are a glass core substrate and a method for manufacturing the same. According to an embodiment of the present invention, there is provided the glass core substrate including: a glass core laminate including a glass layer and insulating layers which are stacked on upper and lower portions of the glass layer; a through hole formed by penetrating through the glass core laminate and provided with at least one crack which is formed at a penetrating inner wall by penetrating into the glass layer; and a conductive material filled in the through hole and the crack. Further, the method for manufacturing a glass core substrate is provided.

This application claims the foreign priority benefit under 35 U.S.C. Section 119 of Korean Patent Application Serial No. 10-2013-0090969 entitled “Glass Core Substrate And Method For Manufacturing The Same” filed on Jul. 31, 2013, which is hereby incorporated by reference in its entirety into this application.

### BACKGROUND OF THE INVENTION

1. Technical Field

The present invention relates to a glass core substrate and a method for manufacturing the same, and more particularly, to a glass core substrate capable of enhancing an adhesion at an interface between a conductive filler in a through hole and a glass layer by forming a crack penetrating into the glass layer at an inner wall of the through hole, and a method for manufacturing the same.

2. Description of the Related Art

Recently, as portable electronic devices including a cellular phone are thinned, warpage occurs due to a mismatch of a coefficient of thermal expansion (CTE) at the time of mounting a semiconductor chip, and the like. In particular, in the case of packaging, there is a need to rapidly solve a problem of the warpage.

In order to improve a warpage characteristic of a substrate, a core using a glass sheet has been developed. However, an adhesion between a glass interface within a machining hole such as a through hole is actually reduced, and thus at the time of plating, a blister 20b, and the like may occur as illustrated in FIG. 4.

In a method for manufacturing a glass core substrate according to the related art, since roughness of the glass interface is approximately 1 mm, the interface adhesion is reduced at the time of forming a seed layer in the case of chemical copper, such that the blister may occur. Further, even in the case of using a sputtering method, when a thermal stress is applied, delamination may easily occur or a conductive layer may not be deposited as it is.

### RELATED ART DOCUMENT

### Patent Document

(Patent Document 1) Korean Patent Laid-Open Publication No. 10-2003-0064269 (Laid-Open Published on Jul. 31, 2003)

(Patent Document 2) Japanese Patent Laid-Open Publication No. 2003-218525 (Laid-Open Published on Jul. 31, 2003)

(Patent Document 3) Japanese Patent Laid-Open Publication No. 2007-145656 (Laid-Open Published on Jun. 14, 2007)

### SUMMARY OF THE INVENTION

An object of the present invention is to provide a technology of enhancing an adhesion at an interface between a conductive filler in a through hole and a glass layer by forming a crack penetrating into the glass layer at an inner wall of the through hole on a glass sheet portion within the through hole.

According to an exemplary embodiment of the present invention, there is provided a glass core substrate, including: a glass core laminate including a glass layer and insulating layers which are stacked on upper and lower portions of the glass layer; a through hole formed by penetrating through the glass core laminate and provided with at least one crack which is formed at a penetrating inner wall by penetrating into the glass layer; and a conductive material filled in the through hole and the crack.

The through hole may be formed so that an internal opening of the through hole at the glass layer in the glass core laminate is narrower than openings of the through hole at upper and lower surfaces of the glass core laminate.

At least one crack may be formed by penetrating in a horizontal direction of the glass layer.

The crack may penetrate into the glass layer by 20 to 100 μm from a boundary between the through hole and the glass layer.

Outer surfaces of the insulating layers may be provided with circuit patterns.

According to another exemplary embodiment of the present invention, there is provided a method for manufacturing a glass core substrate, including: preparing a glass core laminate in which insulating layers are stacked on upper and lower portions of a glass layer; forming a through hole penetrating through the glass core laminate so as to form a crack penetrating into the glass layer at an inner wall of the through hole; and filling a conductive material in the through hole and the crack.

In the forming of the through hole, the through hole may be formed so that an internal opening of the through hole at the glass layer in the glass core laminate is narrower than openings of the through hole at upper and lower surfaces of the glass core laminate.

In the forming of the through hole, at least one crack may be formed by penetrating in a horizontal direction of the glass layer.

In the forming of the through hole, the through hole may be formed by using a laser and the crack may be formed by increasing power of the laser or adding the number of shots to apply impact to the glass layer.

In the forming of the through hole, the through hole may be formed by using any one of CO₂ laser, YAG laser, excimer laser, and UV laser.

In the forming of the through hole, the crack may penetrate into the glass layer by 20 to 100 μm from a boundary between the through hole and the glass layer.

In the preparing of the glass core laminate, the glass core laminate in which outer surfaces of the insulating layers are stacked with thin film conductive sheets may be prepared or the outer surfaces of the insulating layers of the prepared glass core laminate may be stacked with the thin film conductive sheets, and in the forming of the through hole or in the filling of the conductive material, the outer surfaces of the insulating layers may be provided with circuit patterns by machining the thin film conductive sheets.

### BRIEF DESCRIPTION OF THE DRAWINGS

FIG. 1 is a cross-sectional view schematically illustrating a glass core substrate according to an exemplary embodiment of the present invention.

FIG. 2 is an enlarged view of portion ‘A’ of FIG. 1.

FIGS. 3A to 3C are diagrams schematically illustrating each process of a method for manufacturing a glass core substrate according to an exemplary embodiment of the present invention.

FIG. 4 is an enlarged photograph illustrating an interface between a through hole filler and a glass substrate at a glass core substrate according to the related art.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween.

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

The accompanying drawings referred in the present description may be ideal or abstract examples for describing exemplary embodiments of the present invention. In the accompanying drawings, a shape, a size, a thickness, and the like, may be exaggerated in order to effectively describe technical characteristics.

Glass Core Substrate

First, a glass core substrate according to a first aspect according to the present invention will be described in detail with reference to the accompanying drawings. Herein, reference numerals which are not illustrated in the referenced drawings may be reference numerals in other drawings which illustrate the same components.

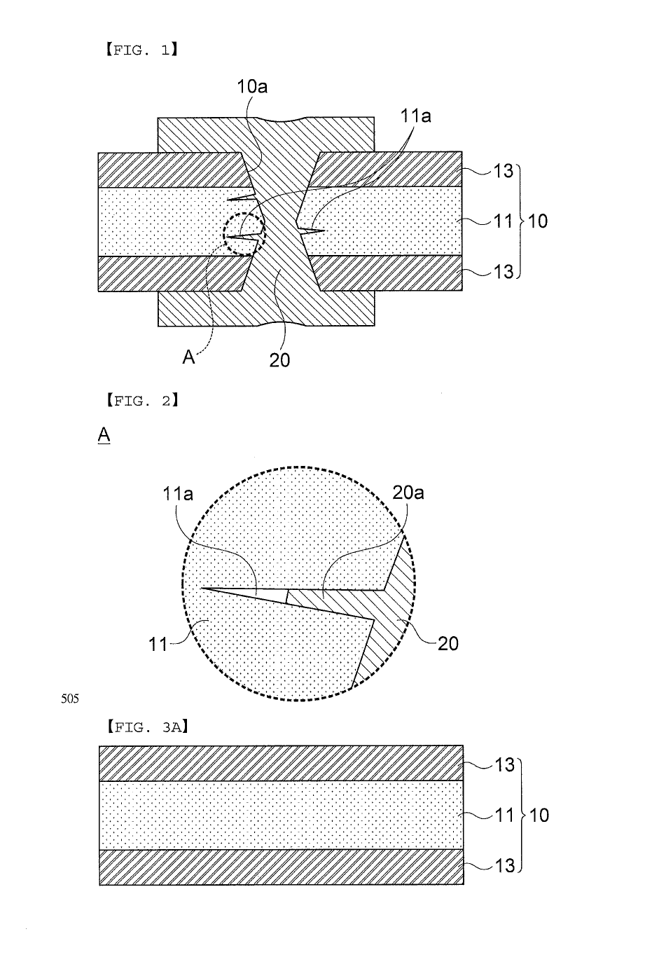

FIG. 1 is a cross-sectional view schematically illustrating a glass core substrate according to an exemplary embodiment of the present invention and FIG. 2 is an enlarged view of portion ‘A’ of FIG. 1.

Referring to FIGS. 1 and 2, the glass core substrate according to one example is configured to include a glass core laminate 10, a through hole 10a, and a conductive material 20. Hereinafter, each components of the glass core substrate will be described in detail. In this case, in describing each component, components which are widely known in the technology field of the glass core substrate within a range keeping features of each component may be used and a description thereof will be omitted.

In detail, referring to FIGS. 1 and 2, the glass core laminate 10 includes a glass layer 11 and insulating layers 13 which are stacked on upper and lower portions of the glass layer 11. The glass layer 11 may be made of a glass material which is used as a substrate material. Further, the insulating layer 13 may be made of a known insulating layer which is used in the glass core substrate. As the insulating material, an epoxy-based resin, and the like, which includes PPG, an ajinomoto build-up film (ABF), ABF glass cloth primer (GCP), poly imide (Pl), primer, a glass fiber, a filler, and the like, may be used. As the glass material, alkali-free glass, and the like may be used and an example of the alkali-free glass may include alumino boro silicate, and the like.

Further, although not illustrated, in one example, outer surfaces of the insulating layers 13 may be provided with circuit patterns. Next, referring to FIGS. 1 and 2, the through hole 10a of the glass core substrate is formed to penetrate through the glass core laminate 10. An inner wall 10a of the penetrating through hole is provided with at least one crack 11a which is formed by penetrating into the glass layer 11. For example, the crack 11a may be formed by forcibly forming a fine crack by applying heat and/or impact to the glass layer 11, for example, using a laser, and the like.

In this case, in one example, the through hole 10a may be formed so that an internal opening of the through hole 10a at the glass layer 11 in the glass core laminate 10 is narrower than openings of the through hole 10a at upper and lower surfaces of the glass core laminate 10. For example, the through hole 10a may be formed to have a diameter which is gradually reduced toward a center of the glass core laminate 10.

In this case, referring to FIGS. 1 and 2, the crack 11a formed in the inner wall 10a of the through hole will be further described.

Referring to FIGS. 1 and 2, at least one crack 11a may be formed. In this case, the crack 11a may be formed at the inner wall 10a of the through hole to penetrate in a horizontal direction of the glass layer 11. For example, the crack 11a may be formed by a method for applying heat and/or impact to the glass layer 11, for example, by increasing a power of laser or the number of shots of laser during a process of forming the through hole.

Further, in one example, the crack 11a may be formed by forcibly forming the fine crack of, for example, 100 μm or less. In this case, the crack 11a is filled with the conductive material 20 while the conductive material 20 filling the through hole 10a is filled in the through hole 10a, such that an adhesion between the glass surface and the conductive material 20, for example, Cu may be enhanced. In this case, the crack 11a may penetrate into the glass layer 11 by 20 to 100 μm from a boundary between the through hole 10a and the glass layer 11. For example, an upper bound size of the crack 11a may be determined in consideration of a minimum pitch interval between the through holes 10a on the substrate. For example, in the case in which the minimum pitch interval between the through holes 10a on the substrate is about 200 μm, when the size of the crack 11a is 100 μm or more, the through holes 10a at both sides are plated and then conducted, such that a short may occur. Further, for example, a lower bound size of the crack 11a may be set to secure the adhesion between the conductive material 20 and the glass layer 11 even in the thermal impact during the following process, for example, the thermal impact during a reflow process, and the like, based on an experimental result. For example, the lower bound size of the crack 11a is set to be about 20 such that the adhesion between the conductive material 20 and the glass layer 11 may be sufficiently secured by a penetration part 20a of the conductive material which penetrates into the crack 11a. For example, a width of the crack 11a is set not to be sufficiently large, for example, may be set to be 5 μm or less.

To be continued, referring to FIGS. 1 and 2, the conductive material 20 of the glass core substrate is filled in the through hole 10a and the crack 11a. For example, the filling of the conductive material may be performed by plating the inside of the through hole 10a and the inside of the crack 11a or may be performed by filling the inside of the through hole 10a and the inside of the crack 11a with the conductive material 20 by a sputtering method, and the like. For example, the conductive material 20 may be made of known metal, and the like which is used in the through hole 10a of the glass core substrate. For example, the inside of the through hole 10a and the inside of the crack 11a may be filled with the conductive material by the plating, the sputtering method, or the like.

For example, referring to FIG. 2, the conductive material 20 filled in the crack 11a may completely fill the crack 11a or may be filled from at least entrance of the crack 11a to a considerable depth. In FIG. 2, reference numeral 20a is a penetration part of the conductive material 20. The adhesion between the conductive material 20 and the glass layer 11 may be secured by the penetration part 20a of the conductive material penetrating into the crack 11a.

FIG. 4 is an enlarged photograph illustrating an interface between a through hole filler and a glass substrate at a glass core substrate according to the related art. Referring to FIG. 4, a result of testing the glass core substrate manufactured without the crack according to the existing method at a peak temperature of 260° C. by using a reflow and solder pot. When the surface roughness is not present in the through hole 10a, the through hole 10a may be vulnerable to the thermal impact during the substrate manufacturing process and as illustrated in FIG. 4, the blister 20b may be frequently generated. Therefore, in the case of the existing method, many tries to form a seed layer (not illustrated) may be actually required.

On the other hand, when the fine crack is forcibly formed as in the exemplary embodiment of the present invention, that is, as illustrated in FIG. 2, fine hole internal plating is completed in the crack 11a in the through hole 10a, such that the adhesion between the conductive material 20 and the glass layer 11 may be enhanced at the thermal impact due to the reflow, and the like, during the substrate manufacturing process.

According to the exemplary embodiments of the present invention, it is possible to remarkably reduce the blister defect frequently occurring due to the low roughness of the glass interface while keeping the existing high modulus characteristic as it is.

Method For Manufacturing Glass Core Substrate

Next, a method for manufacturing a glass core substrate according to a second aspect of the present invention will be described in detail with reference to the accompanying drawings. In this case, the glass core substrate according to the foregoing first aspect and FIGS. 1 and 2 will be referenced and therefore the overlapping description may be omitted.

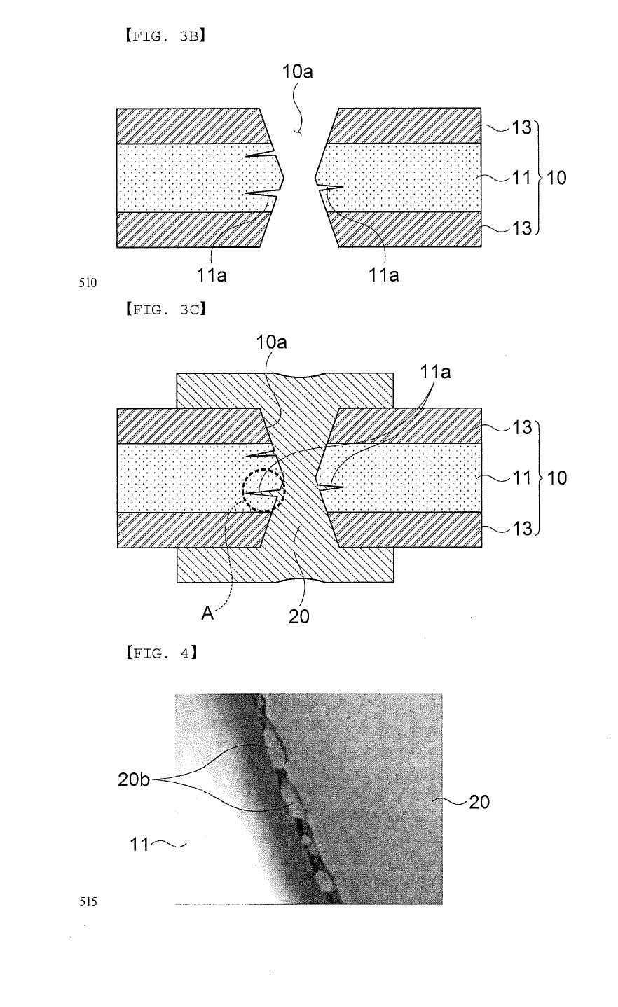

FIGS. 3A to 3C are diagrams schematically illustrating each process of a method for manufacturing a glass core substrate according to an exemplary embodiment of the present invention.

Referring to FIGS. 3A to 3C, the method for manufacturing a glass core substrate according to one example includes preparing the glass core laminate (see FIG. 3A), forming the through hole (see FIG. 3B), and filling the conductive material (see FIG. 3C). Each process will be described in detail with reference to the drawings.

Referring first to FIG. 3A, in the preparing of the glass core laminate, the glass core laminate 10 in which the upper and lower portions of the glass layer 11 are stacked with the insulating layers 13 is prepared. In this configuration, the insulating layers 13 which are stacked on the upper and lower portions of the glass layer 11 may be configured of one insulating sheet as illustrated in FIG. 3A, or although not illustrated, may be configured of a plurality of insulating sheets and a stacked structure in which the circuit patterns (not illustrated) are stacked on each of the insulating sheets. As a material of the glass layer 11 and the insulating layer 13, the known material which is used in the glass core substrate may be used.

Although not illustrated, in one example, in the preparing of the glass core laminate, the glass core laminate 10 formed by stacking thin film conductive sheets on the outer surfaces of the insulating layers 13 may be prepared. Although not illustrated, prior to the forming of the through hole, in the preparing of the glass core laminate, the thin film conductive sheets may be stacked on the outer surfaces of the insulating layers 13 of the prepared glass core laminate 10.

In this case, the thin film conductive sheets (not illustrated) on the outer surfaces of the insulating layers 13 are machined in the following process, such that the circuit pattern (not illustrated) may be formed. For example, the thin film conductive sheets (not illustrated) may be copper clad sheets attached on the surfaces of the insulating layers 13 or may be plated metal conductive layers. For example, in the forming of the through hole or/and the filling of the conductive material, the thin film conductive sheets are machined and thus the outer surfaces of the insulating layers 13 may be provided with the circuit patterns.

Next, referring to FIG. 3B, in the forming of the through hole, the through hole 10a penetrating through the glass core laminate 10 is formed. Further, in the forming of the through hole, the crack 11a penetrating into the glass layer 11 is formed at the inner wall of the through hole 10a.

For example, referring to FIG. 3B, in the forming of the through hole, the through hole 10a is formed so that the internal opening of the through hole 10a at the glass layer 11 in the glass core laminate 10 is narrower than the openings of the through hole 10a at the upper and lower surfaces of the glass core laminate 10.

In this case, referring to FIGS. 3A to 3C, according to one example, in the forming of the through hole, at least one crack 11a may be formed to penetrate into a horizontal direction of the glass layer 11.

Further, in one example, in the forming of the through hole, the through hole 10a may be formed using the laser. The technology of penetrating through the glass core laminate 10 by the laser has been already known.

In this case, in another example, the through hole 10a may be formed by using any one of CO₂ laser, YAG laser, excimer laser, and UV laser.

Further, the crack 11a may be formed by applying heat and/or impact to the glass layer 11 by the method of increasing the power of laser. Further, the crack 11a may be formed by applying the number of shots of laser and applying heat and/or impact to the glass layer 11.

For example, in the forming of the through hole, the crack 11a may penetrate into the glass layer 11 by 20 to 100 μm from the boundary between the through hole 10a and the glass layer 11.

Next, referring to FIG. 3C, in the filling of the conductive material, the inside of the through hole 10a and the inside of the crack 11a are filled with the conductive material 20. For example, the inside of the through hole 10a and the inside of the crack 11a may be filled with the plating material by the plating or the inside of the through hole 10a and the inside of the crack 11a may also be filled with the conductive material by the sputtering method, and the like. For example, the conductive layer 20 may be formed by being plated using the metal, such as Cu, or filled by the sputtering method. For example, in the case of the plating method, the inside of the through hole 10a and the inside of the crack 11a are plated with the seed layer (not illustrated) and then the conductive metal may be plated on the seed layer. For example, the seed layer is formed by an electroless plating method using Ni, Cu, and the like and then the inside of the through hole 10a may be filled by an electroplating method.

According to the exemplary embodiments of the present invention, it is possible to enhance the adhesion at the interface between the conductive filler in the through hole and the glass layer by forming the crack penetrating into the glass layer from at inner wall of the through hole on the glass sheet portion in the through hole.

Further, according to the exemplary embodiment of the present invention, when the fine crack or the crack is forcibly formed, it is possible to increase the adhesion between the conductive material and the glass layer at the time of the thermal impact due to the reflow, and the like during the substrate manufacturing process by filling the crack in the through hole with the conductive material by the fine hole internal plating, and the like, when the fine crack or the crack is forcibly formed.

In addition, according to the exemplary embodiments of the present invention, it is possible to remarkably reduce the blister defect frequently occurring due to the low roughness of the glass interface according to the related art while keeping the high modulus characteristic of the glass core as it is at the time of manufacturing the glass core substrate.

The accompanying drawings and the above-mentioned exemplary embodiments have been illustratively provided in order to assist in understanding of those skilled in the art to which the present invention pertains rather than limiting a scope of the present invention. In addition, exemplary embodiments according to a combination of the above-mentioned configurations may be obviously implemented by those skilled in the art. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A glass core substrate, comprising:
a glass core laminate including a glass layer and insulating layers which are stacked on upper and lower portions of the glass layer;
a through hole formed by penetrating through the glass core laminate and provided with at least one crack which is formed at a penetrating inner wall by penetrating into the glass layer; and
a conductive material filled in the through hole and the crack.

2. The glass core substrate according to claim 1, wherein the through hole is formed so that an internal opening of the through hole at the glass layer in the glass core laminate is narrower than openings of the through hole at upper and lower surfaces of the glass core laminate.

3. The glass core substrate according to claim 1, wherein at least one crack is formed by penetrating in a horizontal direction of the glass layer.

4. The glass core substrate according to claim 1, wherein the crack penetrates into the glass layer by 20 to 100 μm from a boundary between the through hole and the glass layer.

5. The glass core substrate according to claim 2, wherein the crack penetrates into the glass layer by 20 to 100 μm from a boundary between the through hole and the glass layer.

6. The glass core substrate according to claim 3, wherein the crack penetrates into the glass layer by 20 to 100 μm from a boundary between the through hole and the glass layer.

7. The glass core substrate according to claim 4, wherein outer surfaces of the insulating layers are provided with circuit patterns.

8. The glass core substrate according to claim 5, wherein outer surfaces of the insulating layers are provided with circuit patterns.

9. A method for manufacturing a glass core substrate, comprising:
preparing a glass core laminate in which insulating layers are stacked on upper and lower portions of a glass layer;
forming a through hole penetrating through the glass core laminate so as to form a crack penetrating into the glass layer at an inner wall of the through hole; and
filling a conductive material in the through hole and the crack.

10. The method according to claim 9, wherein in the forming of the through hole, the through hole is formed so that an internal opening of the through hole at the glass layer in the glass core laminate is narrower than openings of the through hole at upper and lower surfaces of the glass core laminate.

11. The method according to claim 9, wherein in the forming of the through hole, at least one crack is formed by penetrating in a horizontal direction of the glass layer.

12. The method according to claim 9, wherein in the forming of the through hole, the through hole is formed by using a laser and the crack is formed by increasing power of the laser or adding the number of shots to apply impact to the glass layer.

13. The method according to claim 12, wherein in the forming of the through hole, the through hole is formed by using any one of CO₂ laser, YAG laser, excimer laser, and UV laser.

14. The method according to claim 9, wherein in the forming of the through hole, the crack penetrates into the glass layer by 20 to 100 μm from a boundary between the through hole and the glass layer.

15. The method according to claim 10, wherein in the forming of the through hole, the crack penetrates into the glass layer by 20 to 100 μm from a boundary between the through hole and the glass layer.

16. The method according to claim 11, wherein in the forming of the through hole, the crack penetrates into the glass layer by 20 to 100 μm from a boundary between the through hole and the glass layer.

17. The method according to claim 12, wherein in the forming of the through hole, the crack penetrates into the glass layer by 20 to 100 μm from a boundary between the through hole and the glass layer.

18. The method according to claim 13, wherein in the forming of the through hole, the crack penetrates into the glass layer by 20 to 100 μm from a boundary between the through hole and the glass layer.

19. The method according to claim 14, wherein in the preparing of the glass core laminate, the glass core laminate in which outer surfaces of the insulating layers are stacked with thin film conductive sheets is prepared or the outer surfaces of the insulating layers of the prepared glass core laminate are stacked with the thin film conductive sheets, and
in the forming of the through hole or in the filling of the conductive material, the outer surfaces of the insulating layers are provided with circuit patterns by machining the thin film conductive sheets.

20. The method according to claim 15, wherein in the preparing of the glass core laminate, the glass core laminate in which outer surfaces of the insulating layers are stacked with thin film conductive sheets is prepared or the outer surfaces of the insulating layers of the prepared glass core laminate are stacked with the thin film conductive sheets, and
in the forming of the through hole or in the filling of the conductive material, the outer surfaces of the insulating layers are provided with circuit patterns by machining the thin film conductive sheets.
